(19) United States
(12) Patent Application Publication
(10) Pub. No.: US 2026/0371679 A1
(43) Pub. Date: Nov. 19, 2026

(54) GATE OXIDE MODULE INTEGRATION FOR IMPROVED MOBILITY IN SILICON CARBIDE MOSFETS

(71) Applicant: Applied Materials, Inc., Santa Clara, CA (US)

(72) Inventors: Joshua HOLT, Santa Clara, CA (US); Weiyu YAN, Santa Clara, CA (US); Ramakrishnan BASHYAM, San Jose, CA (US); Ludovico MEGALINI, Mountain View, CA (US)

(21) Appl. No.: 19/676,703

(22) Filed: May 13, 2026

Related U.S. Application Data
(60) Provisional application No. 63/806,604, filed on May 15, 2025.
(60) Provisional application No. 63/817,969, filed on Jun. 4, 2025.

(51) Int. Cl. H10D 64/01; H10D 30/01; H10D 30/66; H10D 62/832; H10D 64/68; H10P 14/60

(52) U.S. Cl. CPC H10D 64/01366; H10D 30/0297; H10D 30/668; H10D 64/685; H10P 14/6506; H10P 14/6512; H10D 62/8325

(57) ABSTRACT

Embodiments of the disclosure include a method for forming a metal-oxide-semiconductor-field-effect-transistor (MOSFET) device. The process will include exposing a surface of a substrate to a process gas comprising hydrogen to form a prepared surface region, wherein the surface of the substrate comprises a silicon carbide containing epitaxial layer; forming a nitrogen-containing layer on the surface of the epitaxial layer; and depositing a gate oxide layer on the nitrogen-containing layer.

### CROSS-REFERENCE TO RELATED APPLICATIONS

This application claims the benefit of U.S. provisional patent application Ser. No. 63/806,604, filed May 15, 2025, and the benefit of U.S. provisional patent application Ser. No. 63/817,969, filed Jun. 4, 2025, which are both herein incorporated by reference.

### BACKGROUND

### Field

The subject matter disclosed herein relates generally to semiconductor device fabrication processes. More particularly, the subject matter disclosed herein relates to systems and methods for producing a MOSFET.

### Description of the Related Art

Silicon carbide (SiC) is a wide gap semiconductor that is being rapidly adopted in power electronic applications due to its high critical electric field, high thermal conductivity, the availability of high-quality large area substrates, and maturing fabrication technology. However, SiC MOSFETs exhibit poor performance due to a high density of interface states, leading to low channel mobility (<5% of bulk mobility) and a high Rdson in the source-drain regions. Rdson, or drain-source on-resistance, refers to the resistance between the drain and source terminals of a MOSFET when the MOSFET is in the “on” state, which is often referred to as a state when it's conducting current. This resistance is an important factor in determining power dissipation and efficiency in MOSFET applications. Recently, low voltage power metal-oxide-semiconductor field-effect transistors (MOSFETs) are often used in load switching applications and in high frequency DC-DC applications where the reduction of the on-resistance (Rdson) of the device is desirable. Silicon carbide (SiC) transistors can often have low mobility and high Rdson, however, due to interface traps at the interface between silicon dioxide (SiO2) and SiC layers. The introduction of nitrogen is known to passivate such traps, improving mobility and Rdson.

FIG. 1A is a side cross-sectional view of a portion of MOSFET device 10 that includes a thermal gate oxide layer 16 disposed between a gate metal 17 and an arrangement of a SiC n-epitaxial layer 13 and a well 14 implanted within a p-type well 15 formed within the epitaxial layer 13 that is formed on a SiC n+substrate 12 and drain 11. The source contact layers 19 are formed over a portion of the well 14. FIG. 1B is a close-up side cross-sectional view of a portion of the MOSFET device 10. FIG. 1C is a side cross-sectional view of the partially formed portion of the MOSFET device 10 after a thermal nitrogen oxide (NO) anneal is applied (e.g., at around 1250° C.) through the gate oxide, which accumulates a nitrogen-containing layer 18 at the desired interface (i.e., between the well 14 and the gate oxide layer 16). This anneal can also oxidize the underlying SiC, however, producing new traps. Because of these competing mechanisms, the benefits of an NO anneal are limited, and mobility is still much lower than bulk SiC.

Accordingly, there is a need for approaches that improve mobility and Rdson through development of a gate oxide module that includes surface preparation operations and introduces nitrogen at the intended interface with minimal or no thermal oxidation of SiC, thereby avoiding the formation of new interface traps.

### SUMMARY

Embodiments of the disclosure may further include a method for forming a metal-oxide-semiconductor-field-effect-transistor (MOSFET) device, comprising: exposing a surface of a substrate to a process gas comprising hydrogen to form a prepared surface region, wherein the surface of the substrate comprises a silicon carbide containing epitaxial layer; forming a nitrogen-containing layer on the surface of the epitaxial layer; and depositing a gate oxide layer on the nitrogen-containing layer. In some embodiments, the process of exposing the surface of the substrate to the process gas to form the prepared surface region is performed in a first processing chamber of a multi-chamber processing system. The process of forming the nitrogen-containing layer on the surface of the epitaxial layer can be performed in a second processing chamber of the multi-chamber processing system, and the process of deposition of the gate oxide layer on the nitrogen-containing layer can be performed in a third processing chamber of the multi-chamber processing system, wherein the substrate is transferred between the first chamber, the second chamber, and the third chamber within a vacuum environment.

Embodiments of the disclosure may further include a metal-oxide-semiconductor-field-effect-transistor (MOSFET) device, comprising: a substrate including an epitaxial layer that comprises silicon carbide (SiC), wherein a surface of the epitaxial layer further comprises a well; a silicon-containing layer formed on the surface of the epitaxial layer, wherein the silicon-containing layer is formed on at least a portion of the well; a nitrogen-containing layer formed on a surface of the silicon-containing layer; and a gate oxide layer on the nitrogen-containing layer, wherein the nitrogen-containing layer is formed over a top surface of the well.

Embodiments of the disclosure may alternately include a method for forming a metal-oxide-semiconductor-field-effect-transistor (MOSFET) device. The process will include exposing a surface of a substrate to a process gas comprising hydrogen to form a prepared surface region, wherein the surface of the substrate comprises a silicon carbide containing epitaxial layer; depositing a silicon containing layer on the prepared surface region; forming a nitrogen-containing layer on the surface of the silicon containing layer; and depositing a gate oxide layer on the nitrogen-containing layer. In some embodiments, the process of exposing the surface of the substrate to the process gas to form the prepared surface region is performed in a first processing chamber of a multi-chamber processing system, and the process of depositing the silicon-containing layer on the prepared surface region is performed in a second processing chamber of the multi-chamber processing system. The process of forming the nitrogen-containing layer on the surface of the silicon-containing layer is performed in a third processing chamber of the multi-chamber processing system, and the process of depositing the gate oxide layer on the nitrogen-containing layer is performed in a fourth processing chamber of the multi-chamber processing system, wherein the substrate is transferred between the first chamber, the second chamber, the third chamber and fourth chamber within a vacuum environment.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a side cross-sectional view of a MOSFET device according to a conventional method.

FIGS. 1B-1C are partial side cross-sectional views of partially formed portions of the MOSFET device illustrated in FIG. 1A according to a conventional method.

FIG. 2A is a side cross-sectional view of an improved MOSFET device according to one or more embodiments of the disclosure provided herein.

FIGS. 2B-2E are partial side cross-sectional views of partially formed portions of the MOSFET device illustrated in FIG. 2A according to one or more embodiments of the disclosure provided herein.

FIG. 3 is a flow chart illustrating a gate oxide module for producing a MOSFET according to an embodiment of the presently disclosed subject matter.

FIG. 4 illustrates an example of an integrated processing system in accordance with embodiments of the present disclosure.

FIG. 5 is a side cross-sectional view of a trench-type MOSFET device according to one or more embodiments of the disclosure provided herein.

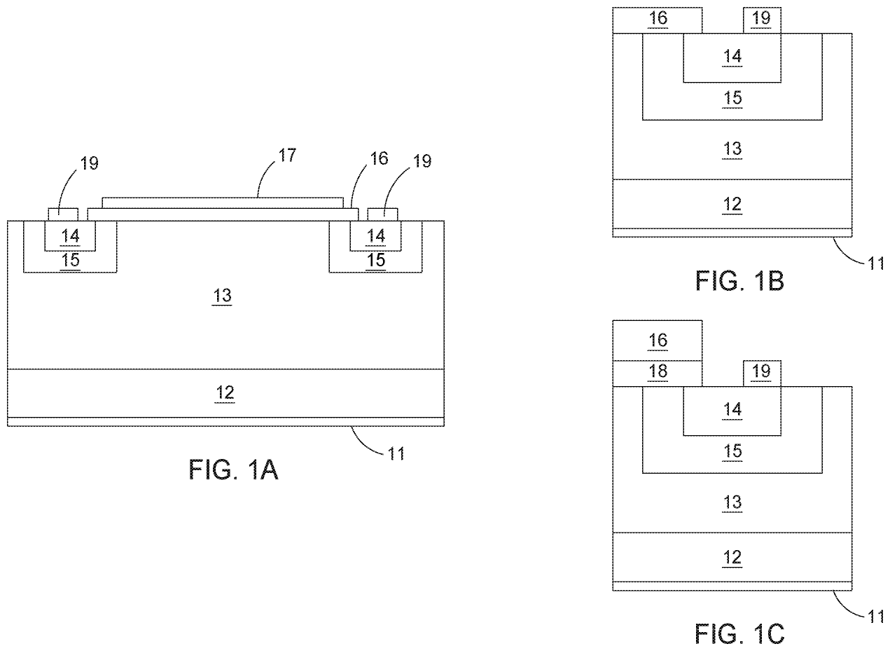

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Methods and devices in accordance with the present disclosure will now be described more fully hereinafter with reference to the accompanying drawings, where various embodiments are shown. The methods and devices may be embodied in many different forms and are not to be construed as being limited to the embodiments set forth herein. Instead, these embodiments are provided so the disclosure will be thorough and complete, and will fully convey the scope of the methods to those skilled in the art.

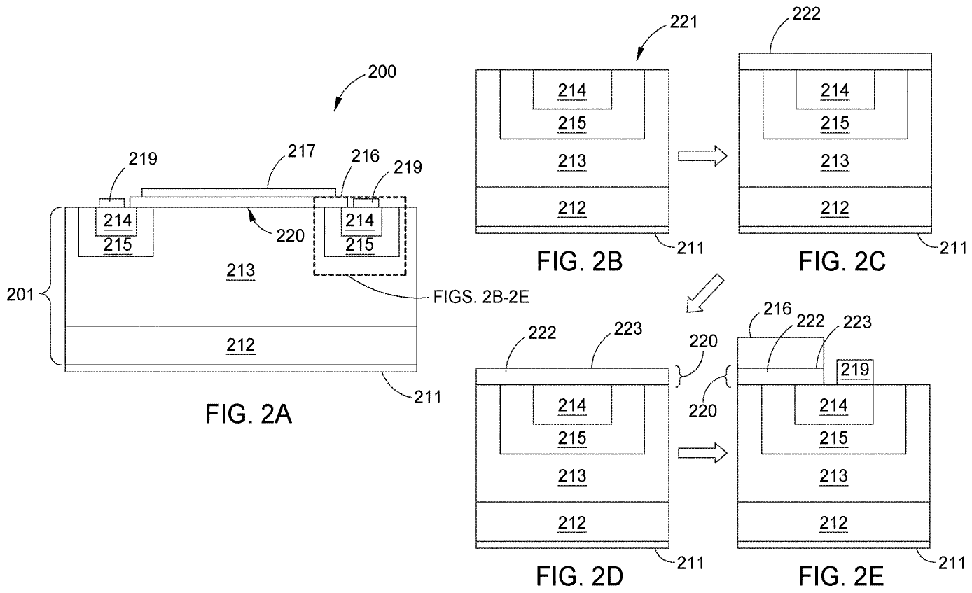

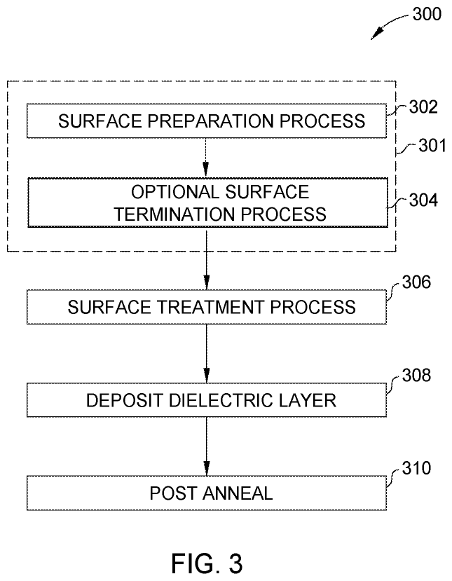

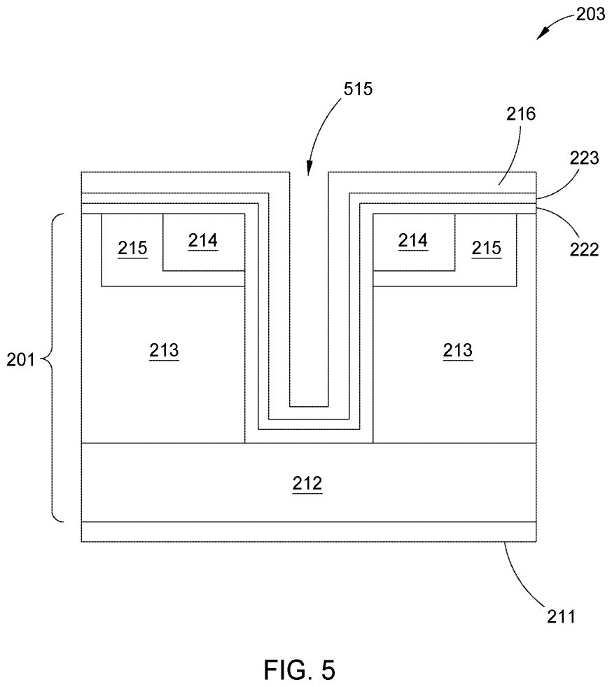

As discussed above, SiC power devices commonly have low mobility and high Rdson due to high interface traps at the gate dielectric-SiC substrate interface (e.g., SiO₂/SiC interface). Thermal oxidation of SiC is known to generate traps, so the conventional use of a furnace gate oxide and an oxidizing post-anneal are both likely contributors to the observed low carrier mobility of these types of MOSFET devices. To address these issues, the present subject matter provides systems and methods for producing a gate oxide layer of a MOSFET by performing one or more surface preparation processing steps, such as a pretreatment process 301 (FIG. 3) and surface treatment process 306 directly on the SiC surface followed by a deposited gate oxide layer. In this way, instead of using a thermal oxide and/or an NO post-anneal process during the formation of a MOSFET device, the one or more surface preparation processing steps, which replace one or more of these steps, can provide a device that has an improved carrier mobility. 211 In one aspect, the present subject matter provides a method for producing a MOSFET device 200, in which a surface of a SiC substrate 201 is pretreated to improve a surface interfacial region on which a gate dielectric layer 216 is positioned. FIG. 2A is a side cross-sectional view of a MOSFET device 200 that includes a gate dielectric layer 216 (e.g., gate oxide layer) disposed between a gate metal layer 217, a gate interfacial region 220, and an arrangement of a SiC n⁻ epitaxial layer 213 and a well 214 implanted within a p-type well 215 that is formed on a SiC n+ substrate 212 and drain 211. The source contact layers 219 are formed over a portion of the well 214. Although not intending to limit the scope of the disclosure, the epitaxial layer 213 may be a SiC n-type drift layer, and the substrate 212 may be a SiC n+ substrate. Although each layer is shown in FIGS. 2A-2E as a single layer, the epitaxial layer 213 and the well 214 and/or p-type well 215 may include multiple layers in other embodiments. While the disclosure provided FIGS. 2A-2E illustrates a planar type MOSFET device 200 to describe one or more novel aspects of the inventive methods described herein, the illustrated device structure is not intended to be limiting as to the scope of the disclosure, since the various embodiments disclosed herein can also be useful for other MOSFET device configurations, such as trench type of MOSFET device which is illustrated in FIG. 5.

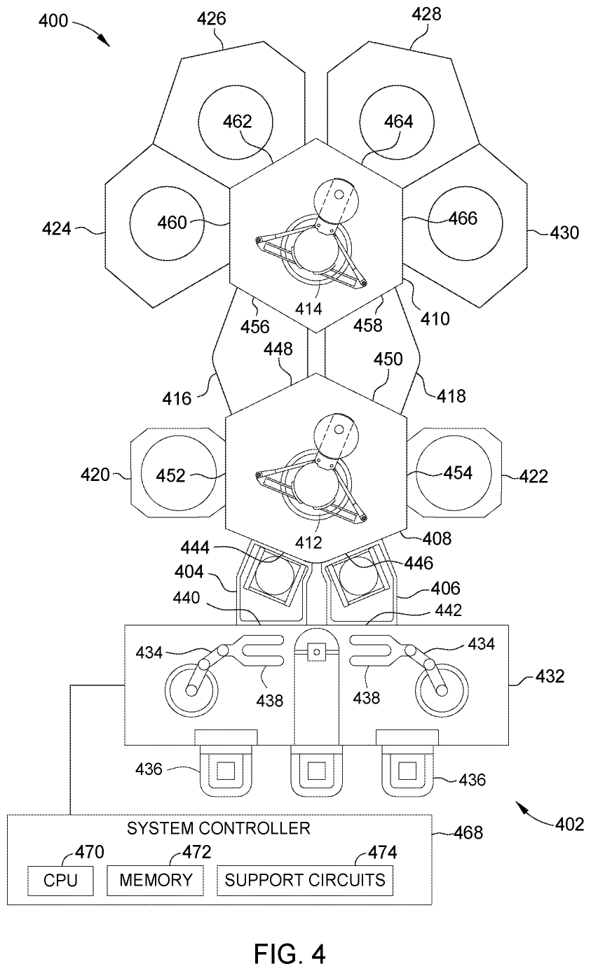

FIG. 3 illustrates a process sequence 300, or method 300, of forming at least a portion of the source-drain regions of the MOSFET device 200. FIGS. 2B-2E are partial side cross-sectional views of a portion of a gate oxide module of the MOSFET device 200 during different portions of the method 300 illustrated in FIG. 3. One or more of the operations 301-310 of the method 300 can be performed in an integrated processing tool, such as a multi-chamber processing system 400 illustrated in FIG. 4.

### Processing System Example

A multi-chamber processing system 400 will generally include a factory interface 402, load lock chambers 404, 406, transfer chambers 408, 410 with respective transfer robots 412, 414, holding chambers 416, 418, and processing chambers 420, 422, 424, 426, 428, and 430. As detailed herein, in some embodiments, substrates in the processing system 400 are processed in and transferred between the various chambers without exposing the substrates to an ambient environment exterior to the processing system 400 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 400. Accordingly, in some embodiments, the processing system 400 may provide for an integrated solution for some processing of substrates.

However, in some embodiments, an ex-situ processing method may be used. The ex-situ processing method will include the performance of a plurality of process steps within a first multi-chamber processing system and a different plurality of process steps being performed within a second multi-chamber processing system. The ex-situ processing method will include a vacuum break step that is needed to transfer the substrates between the first and the second processing systems. In one example, a first set of operations of method 300 are performed in a first multi-chamber processing system (e.g., operations 302-308) and a second set of operations are performed in a second multi-chamber processing system (e.g., operation 310) with a vacuum break being performed between the first set of operations and the second set of operations.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 4, the factory interface 402 includes a docking station 432 and factory interface robots 434 to facilitate transfer of substrates. The docking station 432 is adapted to accept one or more front opening unified pods (FOUPs) 436. In some examples, each factory interface robot 434 generally includes a blade 438 disposed on one end of the respective factory interface robot 434 adapted to transfer the substrates from the factory interface 402 to the load lock chambers 404, 406.

The load lock chambers 404, 406 have respective ports 440, and 442 coupled to the factory interface 402 and respective ports 444, and 446 coupled to the transfer chamber 408. The transfer chamber 408 further has respective ports 448, and 450 coupled to the holding chambers 416, and 418 and respective ports 452, 454 coupled to processing chambers 420, and 422. Similarly, the transfer chamber 410 has respective ports 456, and 458 coupled to the holding chambers 416, 418 and respective ports 460, 462, and 464, and 466 coupled to processing chambers 424, 426, 428, and 430. The ports 444, 446, 448, 450, 452, 454, 456, 458, 460, 462, 464, and 466 can be, for example, slit valve openings with slit valves for passing substrates therethrough by the transfer robots 412, 414 and for providing a seal between respective chambers to prevent a gas from passing between the respective chambers.

The load lock chambers 404, 406, transfer chambers 408, 410, holding chambers 416, 418, and processing chambers 420, 422, 424, 426, 428, and 430 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 434 transfers a substrate from a FOUP 436 through a port 440 or 442 to a load lock chamber 404 or 406. The gas and pressure control system then pumps down the load lock chamber 404 or 406. The gas and pressure control system further maintains the transfer chambers 408, 410 and holding chambers 416, 418 with an interior low pressure or vacuum environment (which may include an inert gas). Hence, the pumping down of the load lock chamber 404 or 406 facilitates passing the substrate between, for example, the atmospheric environment of the factory interface 402 and the low pressure or vacuum environment of the transfer chamber 408.

With the substrate in the load lock chamber 404 or 406 that has been pumped down, the transfer robot 412 transfers the substrate from the load lock chamber 404 or 406 into the transfer chamber 408 through the port 444 or 446. The transfer robot 412 is then capable of transferring the substrate to and/or between any of the processing chambers 420, 422 through the respective ports 452, 454 for processing and the holding chambers 416, 418 through the respective ports 448, 450 for holding to await further transfer. Similarly, the transfer robot 414 is capable of accessing the substrate in the holding chamber 416 or 418 through the port 456 or 458 and is capable of transferring the substrate to and/or between any of the processing chambers 424, 426, 428, 430 through the respective ports 460, 462, 464, 466 for processing and the holding chambers 416, 418 through the respective ports 456, 458 for holding to await further transfer. The transfer and holding of the substrate within and among the various chambers can be in the low pressure or vacuum environment provided by the gas and pressure control system.

The processing chambers 420, 422, 424, 426, 428, and 430 can be any appropriate chamber for processing a substrate. In some examples, the processing chamber 420 can be capable of performing an etch process, the processing chamber 422 can be capable of performing a cleaning process, the processing chamber 424 can be capable of performing a selective removal process, and the processing chambers 426, 428, 430 can be capable of performing respective epitaxial growth processes. The processing chamber 420 may be a Sym3® or Selectra™ Etch chamber available from Applied Materials of Santa Clara, California. The processing chamber 422 may be a Clarion™ or SiCoNi™ Pre-clean chamber available from Applied Materials of Santa Clara, Calif. The processing chamber 426, 428, or 430 may be a Centura® Epi chamber available from Applied Materials of Santa Clara, California. One or more of the processing chambers 424, 426, 428, or 430 may be an atomic layer deposition (ALD), chemical vapor deposition (CVD), plasma enhanced atomic layer deposition (PEALD), or plasma enhanced chemical vapor deposition (PECVD) type of chamber, which is available from Applied Materials of Santa Clara, California.

A system controller 468 is coupled to the processing system 400 for controlling the processing system 400 or components thereof. For example, the system controller 468 may control the operation of the processing system 400 using a direct control of the chambers 404, 406, 408, 410, 416, 418, 420, 422, 424, 426, 428, and 430 of the processing system 400 or by controlling controllers associated with the chambers 404, 406, 408, 410, 416, 418, 420, 422, 424, 426, 428, and 430. In operation, the system controller 468 enables data collection and feedback from the respective chambers to coordinate performance of the processing system 400.

The system controller 468 generally includes a central processing unit (CPU) 470, memory 472, and support circuits 474. The CPU 470 may be any form of a general-purpose processor that can be used in an industrial setting. The memory 472, or non-transitory computer-readable medium, is accessible by the CPU 470 and may be one or more of memory such as random access memory (RAM), read-only memory (ROM), floppy disk, hard disk, or any other form of digital storage, local or remote. The support circuits 474 are coupled to the CPU 470 and may comprise cache, clock circuits, input/output subsystems, power supplies, and the like. The various methods disclosed herein may generally be implemented under the control of the CPU 470 by the CPU 470 executing computer instruction code stored in the memory 472 (or in memory of a particular processing chamber) as, for example, a software routine. When the computer instruction code is executed by the CPU 470, the CPU 470 controls the chambers to perform processes in accordance with the various methods disclosed herein.

Other processing systems can be in other configurations. For example, more or fewer processing chambers may be coupled to a transfer apparatus. In the illustrated example, the transfer apparatus includes the transfer chambers 408, 410 and the holding chambers 416, 418. In other examples, more or fewer transfer chambers (e.g., one transfer chamber) and/or more or fewer holding chambers (e.g., no holding chambers) may be implemented as a transfer apparatus in a processing system.

### Processing Method Example

Referring back to FIGS. 2B-2E and FIG. 3, the method 300 will generally begin with operation 301, in which a pretreatment process is performed on a surface of the substrate 201 of the MOSFET device 200. In some embodiments, the pretreatment process 301 includes a first operation 302, which is referred to herein as a surface preparation process 302, and an optional second operation 304, which is referred to herein as a surface termination process 304.

At operation 302, the surface of the substrate 201, which can include an exposed portion of the SiC n⁻ epitaxial layer 213, a well 214, and p-type well 215, is exposed to a surface preparation process that can include the removal of contaminants formed on the surface of the substrate 201 and a surface etching process to form a prepared surface region 221 (FIG. 2B). The substrate surface may be prepared by performing a process that is configured to remove any damaged SiC containing regions or surface roughness formed on the substrate due to damage created by a prior processing operation, such as an implant process. In some cases, operation 302 can also be used to remove any surface contaminants, such as an oxide layer. In one example, oxides are removed from the surface of the substrate using a process in which the contaminants are removed from the surface of the substrate using a reducing process that includes the exposure of the substrate 201 to hydrogen (H₂) at process temperature of at least 1000° C., such as greater than 1100° C., or greater than 1200° C. In one example, the processing temperature is in a range between 1200° C. and 1400° C. In some embodiments, operation 302 may include the use of a hydrogen-containing reactive gas mixture and/or the use of a vapor containing etchant material. In some examples, operation 302 is performed without the exposure of the substrate surface to a plasma and/or without exposing the substrate to radicals or radical species. In some examples, the process gas may be free of ammonia or a fluorine-containing gas mixture.

The use of high processing temperatures (e.g., ≥1200° C.) and useful gas chemistries (e.g., H₂) during operation 302 are often required to achieve the desired surface properties necessary for forming a desirable MOSFET device. However, it is believed that use of these types of processes will undesirably preferentially remove silicon from the exposed SiC substrate surfaces within the prepared surface region 221, which will leave a higher concentration of carbon on the SiC containing substrate surface, which will undesirably affect the properties (e.g., carrier mobility, interfacial states, etc.) of the gate dielectric-SiC substrate interface.

In an effort to improve the surface properties of the exposed interfacial regions of the substrate 201, at operation 304, the surface of the substrate 201 can be optionally exposed to a surface termination process. In some embodiments of operation 304, a silicon-containing layer is deposited over the surface of the substrate 201 while at least a portion of operation 302 is being performed or after operation 302 has been completed. In other words, in some embodiments, operations 302 and 304 can be performed concurrently, operations 302 and 304 can at least partially overlap in time, or operations 302 and 304 can include separate and distinct process operations. In either case, operations 302 and 304 can be performed in the same process chamber or in separate processing chambers within the multi-chamber processing system 400, such as process chambers 424, 426, 428, or 430. In one or more embodiments, it may be desirable to perform operations 302 and 304 in separate processing chambers to allow certain processing conditions, such as processing temperatures, to be different during each of these two operations.

The process(es) performed during operation 304, can include a deposition process that includes the delivery of a silicon-containing precursor to the surface of the substrate to terminate the exposed surfaces of the substrate 201. In some embodiments, operation 304 includes the termination of dangling bonds formed at the exposed surface of the substrate after performing operation 302. In this case, the deposited silicon material will form part of the lattice structure exposed on the surface of the substrate. In this configuration, the silicon material deposited during operation 304 may only be one or two silicon atoms thick.

In some embodiments, operation 304 includes the formation of a silicon containing layer that has a thickness that is less than 1 nanometer (nm) over the prepared surface region 221. However, in some embodiments, it is desirable to only form a monolayer of a silicon containing layer over the surface of the substrate to avoid the eventual oxidation of a pure silicon (Si) containing portion of a formed layer that is larger than a monolayer during the subsequent gate oxide formation process (i.e., operation 308). In other words, in cases where the deposited silicon containing layer is larger than a monolayer it is believed that the pure silicon containing portion of the formed layer will be oxidized during the subsequent gate oxide formation process (operation 308) which will create an interfacial region that has a decreased mobility and a higher concentration of surface states.

During operation 304, the deposition process can include the use of a silane-containing precursor to deposit a silicon-containing layer on the surface of the substrate 201. In one example, the deposition process includes exposing the substrate 201 to a first process gas containing a silicon precursor and a carrier gas to form a silicon-layer 222 (FIG. 2C) over the prepared surface region 221. In one embodiment, the silicon precursor can be or contain one or more of silane (SiH₄), disilane (Si₂H₆), trisilane (Si₃H₈), tetrasilane (Si₄H₁₀), or any combination thereof precursors. In another embodiment, the silicon-containing precursor is a silicon-chlorine containing precursor, such as monochlorosilane (MCS), dichlorosilane (DCS), trichlorosilane (TCS), tetracholorosilane (STC), hexachlorodisilane (HCDS) or octachlorotrisilane (OCTS). The carrier gas can be or contain one or more of hydrogen (H₂), nitrogen (N₂), argon, helium, or any combination thereof. In one example, the deposition process includes exposure of the substrate 201 to dichlorosilane (DCS) or trichlorosilane (TCS), and hydrogen (H₂) at process temperature of 500° C. or greater, such as greater than 1100° C., such as between 1200° C. and 1300° C.

Next at operation 306, a surface treatment process is performed on the silicon-layer 222 and the prepared surface region 221 to form the gate interfacial region 220. In some embodiments, operation 306 includes the formation of a nitrogen-containing layer 223 by use of a nitridation pre-treatment step, which can be performed using any of a variety of processes including, but not limited to, a thermal or plasma deposition and/or doping/treatment. Operations 306 can be performed in a separate processing chamber within the multi-chamber processing system 400, such as process chambers 424, 426, 428, or 430. In some embodiments, for example, the nitridation pre-treatment can achieved by a plasma nitridation treatment using N₂ at temperatures within a range between room temperature (e.g., between about 15° C. and about 25° C.) and about 400° C. or higher. In other embodiments, the nitridation pre-treatment can be achieved using a rapid thermal nitridation treatment using ammonia (NH₃), such as at temperatures up to about 1100° C. or higher (e.g., at temperatures up to about 1350° C.). In other embodiments, the nitridation pre-treatment can be achieved using a rapid thermal nitridation treatment using N₂, such as at temperatures up to about 1350° C. or higher. In some other embodiments, the nitridation pre-treatment can be achieved by a nitric oxide (NO) anneal process by exposing the substrate to an NO gas, or nitrous oxide (N₂O) gas, at temperatures within a range between 1100° C. and about 1300° C. or higher. In cases where an NO anneal is used, the processing time of the NO anneal process is selected to prevent or minimize the oxidation of the underlying epitaxial SiC layer. In one example, the NO anneal process can be performed for a time that is less than 60 minutes, such as within a range that is between 30 seconds and 60 minutes, between 1 minute and 30 minutes, or even between 2 minutes and 10 minutes. In any configuration, this process for nitridating the interface of the gate oxide can achieve comparable or greater nitrogen concentrations without the risk associated with oxidizing the SiC layers. In some embodiments, mobility improvement (e.g., about 30-40% improvement or greater) can be achieved with the nitrogen-containing layer 223 having a nitrogen concentration of between about 1×10²⁰ cm⁻³ and about 2×10²¹ cm⁻³ or greater.

Next at operation 308, a high-quality gate oxide layer 216 can then be deposited by an appropriate deposition process, such as by atomic layer deposition (ALD), chemical vapor deposition (CVD), low-pressure chemical vapor deposition (LPCVD), or by sputter deposition. Operations 308 can be performed in a processing chamber within the multi-chamber processing system 400, such as process chambers 424, 426, 428, or 430. In some embodiments, the gate oxide layer 216 can be composed of silicon dioxide (SiO₂). Alternatively or in addition, in some embodiments, the gate oxide layer 216 can include one or more high-κ dielectric in place of or in addition to the SiO₂ layer (e.g., on top of the SiO₂ layer). Examples of suitable high-κ dielectric known to those having ordinary skill in the art include, but are not limited to aluminum oxide (Al₂O₃), laminates of SiO₂ and Al₂O₃, hafnium silicate, zirconium silicate, hafnium dioxide, or zirconium dioxide. In any configuration, in contrast to conventional methods in which the gate oxide is generated using furnace oxidation of the underlying SiC layer(s), high-quality deposition of the gate oxide layer 216 (and further deposition of a gate of the MOSFET on the gate oxide layer) can help ensure that the underlying SiC layer(s) is not oxidized.

With the nitrogen-containing layer 223 already developed on the surface prior to deposition of the gate oxide layer 216, any subsequent annealing steps therefore don't need to be specifically designed to enhance the accumulation of nitrogen at the interface. As a result, in some embodiments, a post-anneal can be performed in an inert environment to activate the nitrogen-containing layer 223 and densify the gate oxide layer 216 without risking oxidation of the SiC layers. Alternatively, the post-anneal can be performed in a chemically active environment, but the treatment time and temperature can be selected to avoid oxidation of the SiC layers. In any configuration, because the present post-anneal process does not need to be configured to provide diffusion of nitrogen to the interface between the gate oxide and SiC layers, the post-anneal can be comparatively shorter than conventional methods. Rather, the time and temperature of the anneal can be selected to provide sufficient energy to activate the nitrogen at the interface and/or to sufficiently densify the deposited gate oxide. In some embodiments, for example, the post-anneal process can be performed in an inert furnace environment, such as in an N₂ environment, at a temperature of between about 1100° C. and about 1400° C., and for a period of between about 2 minutes (e.g., for higher of temperatures within the range) and about 3 hours (e.g., for lower of temperatures within the range). In some particular examples, annealing for 30 minutes at about 1250° C. can be effective to produce the device.

In this way, using a comparatively rapid post-anneal can provide the full mobility benefit of nitridation without the disadvantages associated with conventional thermal oxidation anneal processes. In addition, in some embodiments, a single-wafer rapid thermal processing (RTP) post-anneal can efficiently anneal the device, potentially eliminating the need for furnace batch processing.

As illustrated in FIGS. 2B-2E, this process sequence can be applied to produce the MOSFET 200. When combined with a single-wafer gate oxide and single-wafer post-anneal, in some embodiments, this process could eliminate the need for furnace batch processing, possibly bringing a throughput benefit. Alternatively, as illustrated in FIG. 5, similar processes can be applied to form the silicon-layer 222 and introduce nitrogen on trench sidewalls of a trench-based MOSFET configuration 203. As shown in FIG. 5, a plurality of trenches 515 may be formed to form a MOSFET device, such as by using one or more blocking and vertical etch processes to form a sidewall with a slope of approximately 80 to 90 degrees relative to a plane defined by a top surface of the MOSFET device. The process discussed above can then be applied to produce the gate interfacial region 220 that includes the and the prepared surface region 221, the silicon-layer 222 and the nitrogen-containing layer 223 over the device structure, including on sidewalls of the trench 515, prior to the formation of the gate oxide layer 216 being deposited (e.g., by ALD).

Finally, in some embodiments of method 300, an optional post-anneal operation (i.e., operation 310) can be performed to activate the nitrogen-containing layer and densify the gate oxide layer 216. Operations 310 can be performed in a processing chamber within the multi-chamber processing system 400, such as process chambers 424, 426, 428, or 430. Process parameters for each of the operations used to form the gate interfacial region 220, and gate oxide layer deposition, and post-anneal can be optimized to correspondingly enhance the improvement in mobility and Rdson of the device produced. For example, in some embodiments, the nitridation treatment can be optimized to provide the greatest amount of nitrogen while minimizing damage to the SiC (e.g., particularly for plasma treatments). Deposited oxide process parameters can be optimized to minimize defects throughout the oxide. The post-anneal time, temperature, and atmosphere can be optimized to activate the nitrogen at the interface without diffusing too much away and to simultaneously densify the deposited oxide, reducing bulk defects.

In any configuration, as discussed above, the formation of the gate interfacial region 220 can be part of a gate oxide module for producing a MOSFET having improved mobility and reduced Rdson.

It is to be understood that the various layers, structures, and regions shown in the accompanying drawings are schematic illustrations. For ease of explanation, one or more layers, structures, and regions of a type commonly used to form semiconductor devices or structures may not be explicitly shown in a given drawing. This does not imply that any layers, structures, and/or regions not explicitly shown are omitted from the actual semiconductor structures.

As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading the Detailed Description, the various features and functionality described herein may be implemented in any given application and can be implemented in one or more separate or shared modules in various combinations and permutations. Although various features or elements of functionality may be individually described or claimed as separate modules, one of ordinary skill in the art will understand these features and functionality can be shared among one or more common software and hardware elements.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

As used herein, “depositing” and/or “deposited” may include any now known or later developed techniques appropriate for the material to be deposited including yet not limited to, for example: chemical vapor deposition (CVD), low-pressure CVD (LPCVD), and plasma-enhanced CVD (PECVD). Additional techniques may include semi-atmosphere CVD (SACVD) and high-density plasma CVD (HDPCVD), rapid thermal CVD (RTCVD), ultra-high vacuum CVD (UHVCVD), limited reaction processing CVD (LRPCVD), metal-organic CVD (MOCVD), and sputtering deposition. Additional techniques may include ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

While certain embodiments of the disclosure have been described herein, the disclosure is not limited thereto, as the disclosure is as broad in scope as the art will allow and the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A method for forming a metal-oxide-semiconductor-field-effect-transistor (MOSFET) device, comprising:
exposing a surface of a substrate to a process gas comprising hydrogen to form a prepared surface region, wherein the surface of the substrate comprises a silicon carbide containing epitaxial layer;
forming a nitrogen-containing layer on the surface of the epitaxial layer; and
depositing a gate oxide layer on the nitrogen-containing layer.

2. The method of claim 1, wherein the surface of the substrate further comprises a well that comprises one or more silicon carbide layers.

3. The method of claim 2, further comprising performing an annealing process on the gate oxide layer.

4. The method of claim 2, wherein the substrate surface further comprises a trench, wherein a sidewall of the trench includes a portion of the well.

5. The method of claim 1, wherein the epitaxial layer comprises a silicon carbide (SiC) n⁻ epitaxial layer formed on a substrate that comprises a SiC n+ material.

6. The method of claim 1, wherein exposing the surface of the substrate to the process gas is performed at a temperature greater than 1100° C.

7. The method of claim 1, wherein forming the nitrogen-containing layer comprises applying a plasma N₂ treatment to the epitaxial layer.

8. The method of claim 7, wherein the plasma N₂ treatment is applied at temperatures ranging between room temperature and about 400° C.

9. The method of claim 7, wherein forming the nitrogen-containing layer comprises applying a thermal N₂ or NH₃ treatment.

10. The method of claim 7, wherein forming the nitrogen-containing layer comprises performing the treatment in a substantially oxygen free environment.

11. The method of claim 1, wherein forming the nitrogen-containing layer comprises performing a nitric oxide (NO) anneal process by exposing the substrate to NO, or nitrous oxide (N₂O), at temperatures within a range between 1100° C. and about 1300° C.

12. The method of claim 1, wherein
the exposing the surface of the substrate to the process gas to form the prepared surface region is performed in a first processing chamber of a multi-chamber processing system;
the forming the nitrogen-containing layer on the surface of the epitaxial layer is performed in a second processing chamber of the multi-chamber processing system; and
the deposition of the gate oxide layer on the nitrogen-containing layer is performed in a third processing chamber of the multi-chamber processing system, and
wherein the substrate is transferred between the first chamber, the second chamber, and the third chamber within a vacuum environment.

13. The method of claim 12, wherein forming the nitrogen-containing layer comprises applying a plasma N₂ treatment to the epitaxial layer.

14. The method of claim 12, wherein forming the nitrogen-containing layer comprises performing a nitric oxide (NO) anneal process by exposing the substrate to an NO gas, or nitrous oxide (N₂O) gas, at temperatures within a range between 1100° C. and about 1300° C.

15. The method of claim 1, wherein
exposing the surface of the substrate to the process gas to form the prepared surface region is performed in a first processing chamber of a multi-chamber processing system;
forming the nitrogen-containing layer on the surface of the substrate in a second processing chamber of the multi-chamber processing system; and
depositing the gate oxide layer on the nitrogen-containing layer in a third processing chamber of the multi-chamber processing system,
wherein the substrate is transferred between the first chamber, the second chamber, and the third chamber within a vacuum environment.

16. The method of claim 1, wherein exposing a surface of a substrate to a process gas, and forming the nitrogen-containing layer comprises performing the processes in a substantially oxygen free environment.

17. A metal-oxide-semiconductor-field-effect-transistor (MOSFET) device, comprising:
a substrate including an epitaxial layer that comprises silicon carbide (SiC), wherein a surface of the epitaxial layer further comprises a well;
a nitrogen-containing layer formed on a surface of the epitaxial layer; and
a gate oxide layer on the nitrogen-containing layer,
wherein the nitrogen-containing layer is formed over a top surface of the well.

18. The MOSFET of claim 17, wherein the substrate comprises a planar MOSFET configuration.

19. The MOSFET of claim 17, wherein the substrate comprises one or more trenches formed within the epitaxial layer; and
wherein the nitrogen-containing layer is formed on sidewalls of the one or more trenches.

20. The MOSFET of claim 17, wherein the gate oxide layer comprises one or more of SiO₂ or a high-κ dielectric material.
